(19) United States
(12) Patent Application Publication
(10) Pub. No.: US 2026/0190234 A1
(43) Pub. Date: Jul. 2, 2026

(54) PRINTED CIRCUIT BOARD MODULE

(71) Applicant: CANON KABUSHIKI KAISHA, Tokyo (JP)

(72) Inventor: SHINJI OBANA, Tokyo (JP)

(21) Appl. No.: 19/409,106

(22) Filed: Dec. 4, 2025

(30) Foreign Application Priority Data
Dec. 26, 2024 (JP) 2024-230752

(51) Int. Cl. H05K 1/14; H05K 1/18

(52) U.S. Cl. CPC H05K 1/144; H05K 1/181; H05K 2201/042; H05K 2201/049; H05K 2201/10015; H05K 2201/10022; H05K 2201/10159; H05K 2201/10189; H05K 2201/10212; H05K 2201/10242

(57) ABSTRACT

A printed circuit board module includes a first printed circuit board having a first surface mounted with a processor component, a second printed circuit board separated from the first printed circuit board and having a second surface mounted with a memory component and parallel to the first surface, a connection member disposed between the first and second printed circuit boards so that the connection member opposes a first side of the processor component in a projection view in a first direction perpendicular to the first surface, the connection member electrically connecting the first and second printed circuit boards, and a plurality of support members disposed between and supporting the first and second printed circuit boards. The plurality of support members are disposed apart from each other and each of the support members is disposed apart from the connection member.

### BACKGROUND

### Field of the Technology

The aspect of the disclosure relates to one or more embodiments of a printed circuit board (PCB) module (also referred to as a printed wiring board (PWB) module).

### Description of the Related Art

Japanese Patent Application Laid-Open No. 2006-120736 discloses a PCB module in which a plurality of PCBs are stacked and mounted using a standoff substrate (spacer substrate) in order to suppress an increase in mounting area.

However, in the PCB module disclosed in Japanese Patent Application Laid-Open No. 2006-120736, a region near the mounting area of the standoff substrate to be joined to an external substrate may cause constraints on the arrangement of electronic components and on the surface-layer wiring of the external substrate.

### SUMMARY

One or more embodiments of a printed circuit board module according to one or more aspects of the disclosure may include a first printed circuit board having a first surface on which a processor component is mounted, a second printed circuit board having a second surface on which a memory component is mounted, the second surface being parallel to the first surface, and the second printed circuit board being disposed apart from the first printed circuit board, a connection member mounted on and disposed between the first printed circuit board and the second printed circuit board so that the connection member opposes a first side of a package outer shape of the processor component in a projection view in a first direction perpendicular to the first surface, the connection member electrically connecting the first printed circuit board and the second printed circuit board, and a plurality of support members disposed between the first printed circuit board and the second printed circuit board and supporting the first and second printed circuit boards. The plurality of support members are disposed apart from each other and each of the plurality of support members is disposed apart from the connection member.

Features of the present disclosure will become apparent from the following description of embodiments with reference to the attached drawings. The following description of embodiments is described by way of example.

### BRIEF DESCRIPTION OF THE DRAWINGS

FIGS. 1A, 1B, and 1C are schematic diagrams of a PCB module according to a first embodiment.

FIGS. 2A, 2B, 2C, and 2D explain the PCB module according to the first embodiment.

FIGS. 3A and 3B are schematic structure diagrams of the PCB module according to the first embodiment.

FIG. 4 is an exploded perspective view schematically illustrating a PCB module according to a second embodiment.

FIG. 5 is an exploded perspective view schematically illustrating a PCB module according to a third embodiment.

FIGS. 6A and 6B are schematic diagrams of a PCB module according to a fourth embodiment.

FIGS. 7A and 7B are schematic diagrams of a PCB module according to a fifth embodiment.

FIGS. 8A and 8B are schematic diagrams of a PCB module according to a sixth embodiment.

FIGS. 9A and 9B are schematic diagrams of a PCB module according to a seventh embodiment.

FIGS. 10A and 10B are perspective views illustrating the structure of a conventional PCB module.

### DESCRIPTION OF THE EMBODIMENTS

Referring now to the accompanying drawings, a detailed description will be

given of embodiments according to the disclosure. Corresponding elements in respective figures will be designated by the same reference numerals, and a duplicate description thereof will be omitted.

### First Embodiment

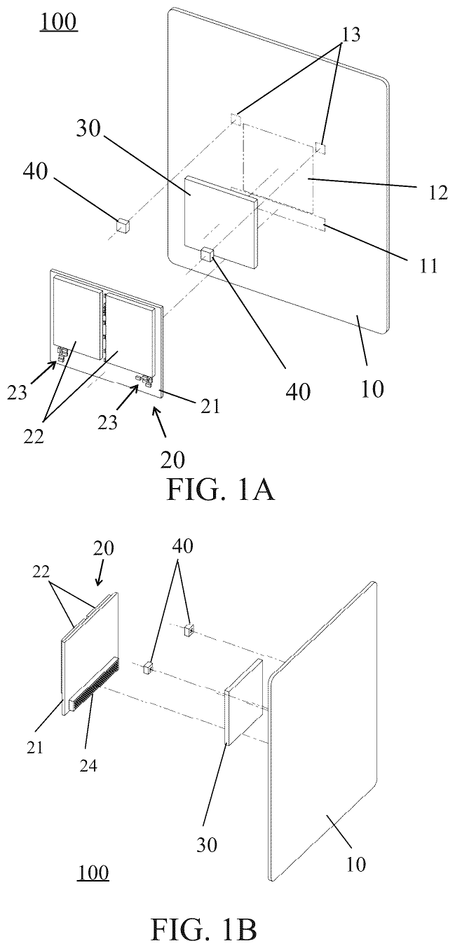

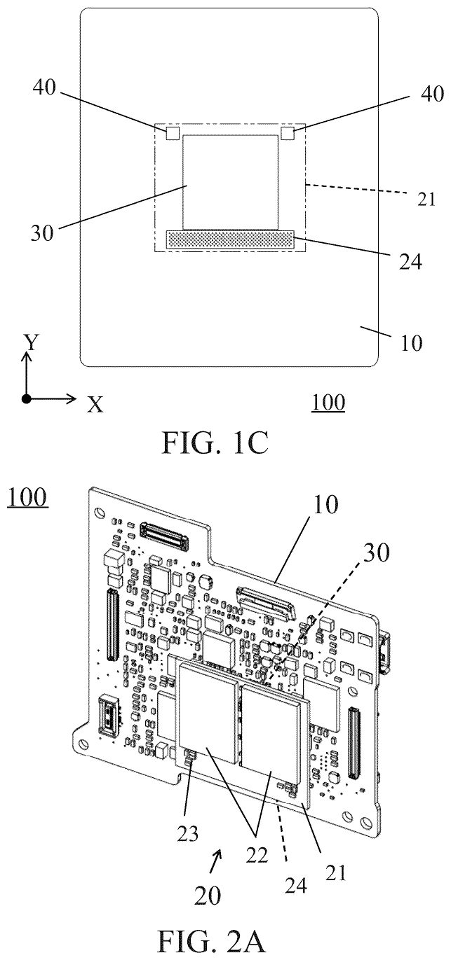

FIGS. 1A, 1B, and 1C are schematic diagrams of a PCB module 100 according to this embodiment. FIGS. 1A and 1B are exploded perspective views of the PCB module 100, and FIG. 1C is a front view of the PCB module 100. In FIG. 1C, for convenience of illustration, an intermediate substrate 21 is illustrated as being transparent.

The PCB module 100 includes a main substrate 10, which is formed by alternately laminating a plurality of insulating layers and conductive layers, and a variety of mounted components implemented on the main substrate 10. An intermediate substrate module 20 is one of the components mounted on the main substrate 10. The intermediate substrate module 20 includes an intermediate substrate 21. The intermediate substrate 21 includes Random Access Memories (RAMs) 22, passive electronic components 23, and an intermediate connection member 24. In this embodiment, the RAMs 22 and the passive electronic components 23 are mounted on a front surface of the intermediate substrate 21, and the intermediate connection member 24 is mounted on a rear surface of the intermediate substrate 21. The intermediate substrate 21 is a PCB having a structure in which a plurality of insulating layers and conductive layers are alternately laminated. In this embodiment, two RAMs 22 are mounted on the intermediate substrate 21. Examples of the memory include Dynamic RAM (DRAM) and Static RAM (SRAM); however, the disclosure is not limited to this example, and other types of memory may be used. The passive electronic components 23 are general-purpose components such as chip resistance elements and ceramic capacitors. The intermediate connection member 24 has a double-sided board structure, in which through-holes are formed at predetermined intervals in a base material made of an insulating material, thereby allowing electrical conduction between both sides. After the inside of the through-holes are sealed (or filled) with a sealing material such as resin, plating is applied to the surfaces of the lands (pad portions) on both sides to form mounting lands directly above the through-holes.

In addition to the intermediate substrate module 20, a video processing IC 30 and spacers (support members) 40 are mounted on the main substrate 10. The video processing IC 30 is an IC package incorporating a video processing processor and including, in addition to a CPU core, a memory area, a timer function, and input/output (I/O) ports. Each spacer 40 has a double-sided board structure and is provided with mounting lands on one surface thereof, the mounting lands being mountable on the main substrate 10. The main substrate 10 includes mounting lands for mounting the intermediate substrate module 20, the video processing IC 30, and the spacers 40. These mounting lands include conductive pads formed in arbitrary shapes on the surface insulating layer, and mounting lands corresponding to the electrode shapes of the mounted components are defined by the etching pattern of the solder resist that protects the surface wiring.

The intermediate substrate module 20 is mounted on the main substrate 10 such that an intermediate-connection-member mounting land 11 and the mounting land of the intermediate connection member 24 are opposite to each other. The video processing IC 30 is mounted on the main substrate 10 such that its electrodes and a video-processing-IC mounting land 12 are opposite to each other. Each spacer 40 is mounted such that its mounting land and a spacer mounting land 13 are opposite to each other.

In this embodiment, both the video processing IC and the RAM are mounted; however, other processor components incorporating an image processing processor and other memory components capable of recording tasks executable by the processor may be mounted instead.

In this embodiment, a surface opposite to the surface of the intermediate substrate 21 on which the RAM 22 is mounted faces the surface of the main substrate 10 on which the video processing IC 30 is mounted. However, the disclosure is not limited to this structure. The surface of the intermediate substrate 21 on which the RAM 22 is mounted may also face the surface of the main substrate 10 on which the video processing IC is mounted. In such a case, the overall height of the PCB module 100 can be reduced.

The video processing IC 30 is disposed between the main substrate 10 and the intermediate substrate module 20. The video processing IC 30 has a rectangular package outer shape and is mounted on the main substrate 10 such that, in a projection view in a direction perpendicular to the surface on which the video processing IC 30 is mounted, its one side (first side) opposes one side on the substrate-outer-shape long side of the intermediate connection member 24. The spacers 40 are mounted on the main substrate 10 so as to be close to both end portions of a package outer shape side (second side) of the video processing IC 30, which is opposite to the side facing the intermediate connection member 24. The intermediate substrate 21 has a rectangular substrate outer shape, and the intermediate connection member 24 is previously mounted near one side thereof. When the intermediate substrate module 20 is mounted on the main substrate 10 in this state, each component and the video processing IC 30 is mounted so as to be surrounded by the intermediate connection member 24 and the two spacers 40, and the substrate outer shape of the intermediate substrate 21 covers the package outer shape of the video processing IC 30. In this embodiment, in the projection view in the direction perpendicular to the surface on which the video processing IC 30 is mounted, the combined projected area of the intermediate connection member 24 and the two spacers 40 is 50% or less of the projected area of the video processing IC 30. The combined projected area of the intermediate connection member 24 and the two spacers 40 may be 40% or less, or 30% or less of the projected area of the video processing IC 30.

The intermediate substrate module 20 is supported by three components: the intermediate connection member 24 and the two spacers 40. The video processing IC 30 performs a variety of functions such as video correction, codec processing, and format conversion, requiring a large amount of computation in a short time. The RAM 22 temporarily stores operation data processed by the video processing IC 30. In the intermediate substrate module 20, wiring patterns formed inside the intermediate substrate 21 electrically connect the respective electrodes of the RAM 22 and the intermediate connection member 24 to each other. In the PCB module 100, the video processing IC 30 and the RAM 22 are electrically connected via the wiring patterns of the main substrate 10, the intermediate connection member 24, and the intermediate substrate 21. Since a large amount of computation data is transmitted at high speed between the video processing IC 30 and the RAM 22, a large number of wiring lines are required for electrical connection. Hence, by arranging them close to each other, the wiring area on the main substrate 10 can be reduced.

By disposing the intermediate substrate 21 above the video processing IC 30 and electrically connecting the video processing IC 30 and the RAM 22 via the intermediate connection member 24, the component mounting area on the main substrate 10 can be reduced. Although the package outer shape of the RAM 22 generally occupies a larger mounting area than other components such as transistors or regulator ICs, the three-dimensional mounting structure of this embodiment achieves a significant reduction in the mounting area of the main substrate 10. Although some of the wiring connections between the video processing IC 30 and the RAM 22 include passive elements such as resistance elements, most of the wiring directly connects the video processing IC 30 and the RAM 22. Therefore, the influence of the three-dimensional mounting structure of the RAM 22 on other circuit connections can be minimal.

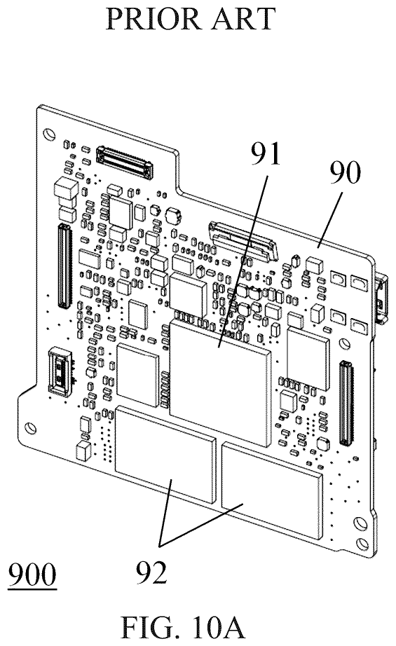

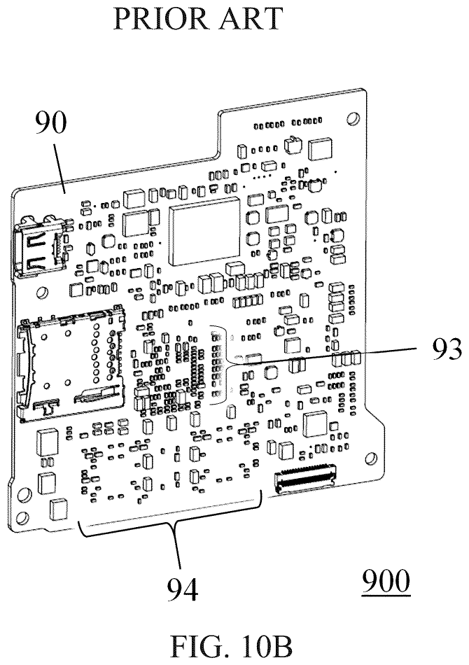

FIGS. 10A and 10B are perspective views illustrating the structure of a conventional PCB module 900. The PCB module 900 includes a main substrate 90. Mounted on the surface of the main substrate 90 are an image processing IC 91 and a RAM 92. In order for the image processing IC 91 and the RAM 92 to perform high-speed computation processing in a stable manner, bypass capacitors may be disposed at short distances from their respective power supply electrodes so as to achieve compact electrical connection. To suppress inflow of noise generated during operation of the electronic apparatus into the power supply line, a bypass capacitor is mounted near the image processing IC 91 so as to reduce the AC impedance between the power supply line and ground, thereby suppressing noise generation. Accordingly, on the back surface of the main substrate 90, bypass capacitors for respective power supplies are mounted at positions corresponding to the locations directly below the power supply electrodes. Video-processing-IC passive electronic components 93 include bypass capacitors that are electrically connected to the power supply electrodes of the image processing IC 91. RAM passive electronic components 94 include bypass capacitors that are electrically connected to the power supply electrodes of the RAM 92. In order to achieve stable operation during high-speed computation processing, the main substrate 90 connects the power supply wirings to the power supply electrodes on the back surface via vias or through-holes from mounting lands on which the power supply electrodes are mounted, so as to connect to the bypass capacitor electrodes along a short path. Thus, layout constraints for the bypass capacitors arise across the region occupied by the package outer shapes of the image processing IC 91 and the RAM 92, thereby leading to constraints on arrangement of other electronic components and on wiring of other circuits.

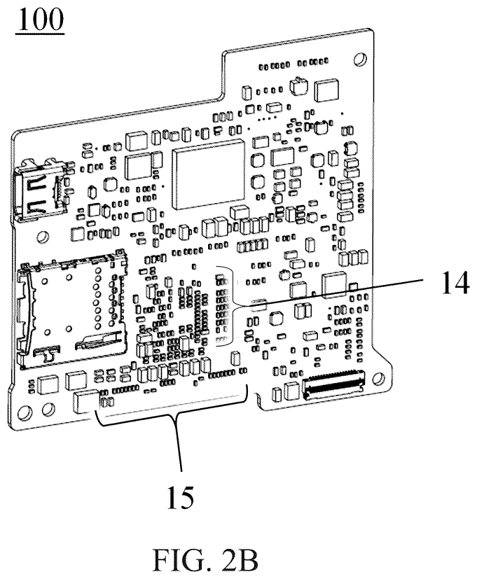

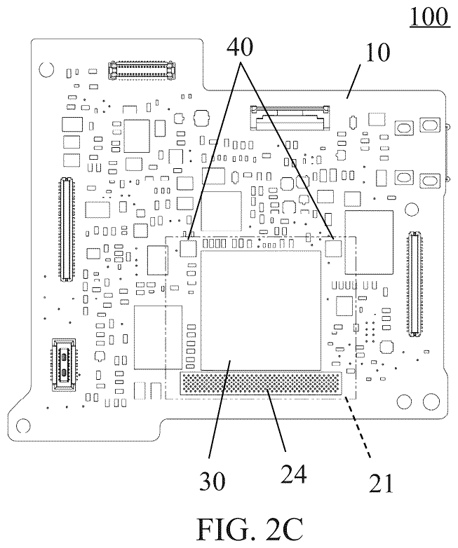

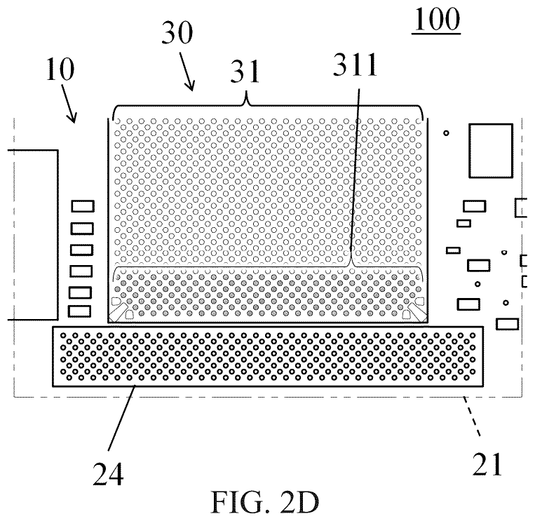

FIGS. 2A, 2B, 2C, and 2D explain the PCB module 100. FIGS. 2A and 2B are perspective views of the PCB module 100. FIG. 2C is a front view of the PCB module 100, in which the intermediate substrate 21 is illustrated as transparent for convenience of illustration. FIG. 2D is a partially enlarged view of the PCB module 100, particularly illustrating the video processing IC 30 and the intermediate substrate 21.

On the back surface of the main substrate 10, which is opposite to the surface on which the video processing IC 30 and the intermediate connection member 24 are mounted, an image-processing-IC passive electronic components 14 and RAM passive electronic components 15 are mounted in a similar manner as in the conventional structure. The connection electrodes of the intermediate connection member 24 to the main substrate 10 are densely arranged with a narrow pitch, and among these numerous electrodes arranged in a dense narrow-pitch structure, bypass capacitors are mounted for the power supply electrodes. Hence, the mounting area occupied by the RAM passive electronic components 15 can be confined within an area smaller than that occupied by the conventional RAM passive electronic components 94. As a result, the main substrate 10, as well as the electronic apparatus equipped with the main substrate 10, can be reduced in size.

The video processing IC 30 includes multiple electrodes (electrode portions) 31, which are electrically connected to other ICs for operating and controlling the PCB module 100. The electrodes 31 are previously assigned to a variety of ports for respective circuit blocks, such as ports connected to electronic components of an imaging circuit system and ports connected to circuit components of a wireless communication system.

In this embodiment, as illustrated in FIG. 2D, the electrodes 31 include RAM communication electrodes (first electrode portions) 311 that are formed in several rows at a position adjacent to one side of the package outer shape of the video processing IC 30. By arranging the intermediate connection member 24 in this manner, the wiring length of wiring patterns connecting the video processing IC 30 and the RAM 22 on the main substrate 10 can be reduced. Depending on the type of processor unit applied, it is conceivable that the RAM communication electrodes 311 are not necessarily integrated along a single side of the package outer shape. In such a case, by positioning the intermediate connection member 24 to face the side where the RAM communication electrodes 311 are most integrated, the wiring pattern connecting the video processing IC 30 and the RAM 22 on the main substrate 10 can still be reduced.

In this embodiment, the intermediate substrate module 20 is supported by the intermediate connection member 24 and two spacers 40. Unlike the structure in which a frame-shaped standoff substrate surrounds the periphery of the video processing IC 30, a certain gap is formed between these three members. Other electronic components may be disposed within this gap, and signal wiring patterns may also be formed on the surface conductor layer of the main substrate 10. For example, among the wirings connecting the video processing IC 30 to other ICs, there may be wirings that form high-speed transmission lines configured to control characteristic impedance along wiring paths within the main substrate 10. In such impedance control lines (Z-control lines), a conductor layer adjacent in the lamination direction relative to the wiring layer may be set as a reference layer. The reference layer may be formed as a ground plane or a ground mesh line, or alternatively, the conductor layer adjacent to the wiring layer may be removed and the next closest conductor layer may be designated as the reference layer. Such measures are suitably optimized according to the substrate material and layer structure of the main substrate 10, in accordance with the intent of impedance control. Since such Z-control lines primarily impose wiring constraints on adjacent layers within the projection range of the wiring region, when a Z-control line is routed on an inner conductor layer of the main substrate 10, wiring constraints arise on conductor layers adjacent to that layer on both sides. Accordingly, routing a Z-control line on a surface conductor layer allows wiring constraints to be confined to only one inner conductor layer adjacent thereto, thereby increasing the wiring density of the main substrate 10 and reducing the size of the substrate. In particular, in the case of the video processing IC 30 applicable to an electronic apparatus such as an image pickup apparatus, the substrate wiring may include a plurality of high-speed transmission lines, such as imaging signal lines, wireless communication signal lines, and Universal Serial Bus (USB) standard wirings. Thus, configuring the area around the video processing IC 30 to allow surface wiring enables reduction in the substrate size and a decrease in the number of layer structures. Furthermore, since the electrodes and mounting lands of the intermediate connection member 24 are formed in a narrow pitch near the electrode portion of the video processing IC 30, the space for arranging other electronic components can be secured within the gap formed between the intermediate connection member 24 and the spacer 40. Thus, in the PCB module 100, component placement can be achieved with a high component mounting density.

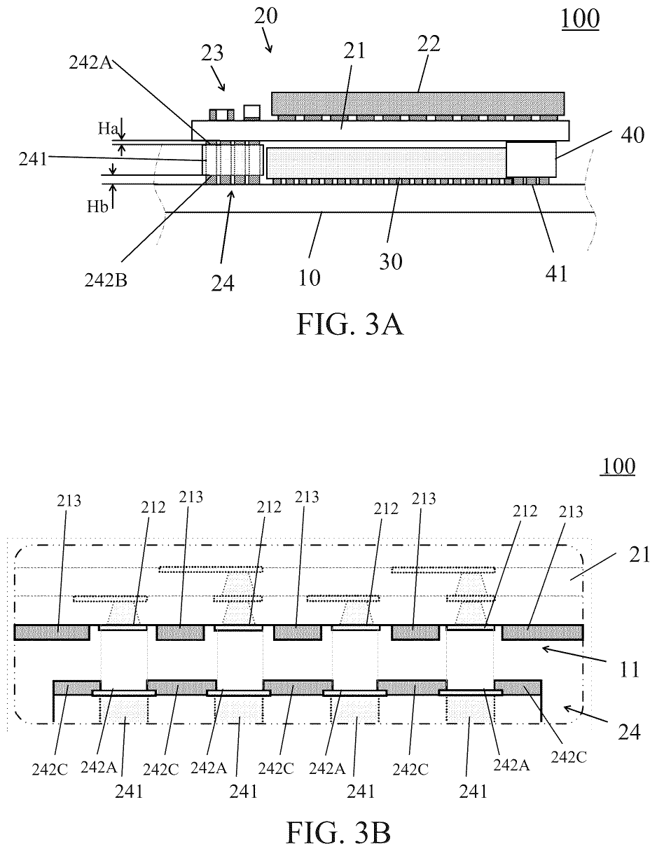

FIGS. 3A and 3B are schematic structure diagrams of the PCB module 100. FIG. 3A is a schematic side view of the PCB module 100 illustrating the mounting portion of the video processing IC 30. In this embodiment, each spacer 40 forms a mounting land 41, is soldered to the main substrate 10, and supports the intermediate substrate module 20. No fixed joining, such as solder joint, is performed between the spacer 40 and the intermediate substrate 21; rather, they are configured to be supported in contact only.

Here, the clearance in the substrate thickness direction between the intermediate substrate module 20 and the main substrate 10 is properly set based on the component height of the video processing IC 30, variation thereof, and variation of solder joint portion “mounting float” during component mounting. The substrate layer structure of the intermediate connection member 24 is determined to satisfy this clearance. To ensure a stable solder joint between the main substrate 10 and the intermediate connection member 24, a predetermined amount of gap is provided so that the intermediate substrate module 20 does not come into contact with the video processing IC 30 when the intermediate substrate module 20 is mounted. The electronic components disposed within the predetermined amount of gap formed between the intermediate connection member 24 and the spacer 40 are selected to have component heights equal to or less than that of the video processing IC 30. In a case where an electronic component having a component height exceeding that of the video processing IC 30 is to be mounted, the component is mounted at a position not overlapping the projection of the substrate outer shape of the intermediate substrate module 20, thereby avoiding contact with the intermediate substrate module 20. Due to this structure, the height of the intermediate substrate module 20 can be minimized, thereby suppressing an increase in the overall size of the PCB module 100 and of the electronic apparatus incorporating the PCB module 100.

If the spacer 40 and the intermediate substrate 21 are soldered together, the intermediate substrate module 20 is fixed and held in a plurality of regions, namely, a region where the spacer 40 is disposed and a region where the intermediate connection member 24 is disposed. In such a case, when the intermediate substrate 21 or the main substrate 10 undergoes warpage or deformation due to environmental temperature variations or the like, stresses corresponding to the deformation amount are concentrated on each solder joint portion. When the stress concentration exceeds a permissible limit, the solder joint portion may fracture, thereby potentially causing a malfunction of the PCB module 100. To enhance the reliability of solder joint portions, the PCB module 100 is configured such that the fixed holder is limited to the region of the intermediate connection member 24, thereby reducing stress concentration on the solder joint portion in the event that either of the substrates is deformed. In this embodiment, the spacer 40 is mounted on the main substrate 10; however, the disclosure is not limited to this example. For example, the spacer 40 may alternatively be mounted on the intermediate substrate 21 so as to be in contact-supported engagement with the main substrate 10. In such a structure, component mounting lands near the video processing IC 30, where signal electrodes are concentrated and wiring density tends to be high, can be reduced, thereby increasing the degree of wiring freedom of the main substrate 10.

In a case where the intermediate substrate module 20 is mounted on the main substrate 10, stable component mounting can be achieved, and occurrence of mounting defects can be reduced by performing solder reflow while maintaining the surface of the intermediate substrate 21 substantially parallel to the surface of the main substrate 10. However, due to slight warpage generated during manufacturing of each substrate and variations in substrate thickness, it is difficult to maintain perfect parallelism between the substrates during solder reflow. If solder reflow is performed while the substrates are tilted relative to each other, solder bridging defects may occur at a solder joint portion located in an area where the substrates are close to each other, as solder is extruded from the mounting lands. In addition, open defects may occur at a solder joint portion located in an area where the substrates are separated from each other. Accordingly, the substrate thicknesses of the intermediate connection member 24 and the spacer 40 substantially equal and the intermediate substrate module 20 mounted on the main substrate 10 in a substantially parallel state can suppress the occurrence of such mounting defects. One specific method for achieving this state is to arrange the intermediate connection member 24 and the spacers 40 on the same worksheet (panel). Since the individual substrate pieces within the same worksheet are manufactured through substantially the same processes and timing, their substrate thicknesses can be relatively uniform. Therefore, by cutting (separating) both the intermediate connection member 24 and the spacers 40 from the same worksheet, the thicknesses of both substrates that support both ends of the intermediate substrate 21 can be made substantially uniform.

In extracting individual pieces of the intermediate connection member 24 and the spacer 40 from the worksheet, several formation methods are conceivable. Among them, when a substrate outer shape of each piece is very small and a predetermined processing accuracy is required for the outer dimension, the outer shape process using a dicing process may be selected. The dicing process is a commonly used method for singulating chip pieces from a semiconductor wafer, wherein the substrate is fixed to a UV tape, diced with a blade, and then subjected to a cleaning process to extract the individual pieces. When such a processing method is adopted, the substrate outer shape is formed as a rectangular shape, and the substrate outer shape can be formed by performing dicing in two orthogonal directions. By forming the substrate outer shapes of the intermediate connection member 24 and the spacer 40 through such a highly accurate processing method, the outer shape of each substrate can be processed while the mounting lands are close to each other. Therefore, the outer area of each substrate can be reduced, thereby increasing the component mounting density near the video processing IC 30.

As described above, the intermediate connection member 24 electrically connects the intermediate substrate 21 and the main substrate 10. However, due to thermal warpage or deformation of the substrates during reflow mounting, there is a concern that mounting defects such as solder bridging or open circuits may occur at the solder joint portion between the substrates. In the PCB module 100, the outer size of the intermediate substrate 21 is smaller than that of the main substrate 10. The intermediate substrate 21 generally has a substrate outer shape of a substantially rectangular shape, whereas the main substrate 10 often has a more complex outer shape, including partial cutouts or perforation holes, depending on a relationship with other components of the electronic apparatuses (or devices) to be mounted. Thus, the main substrate 10 tends to exhibit a greater amount of thermal warpage during reflow than the intermediate substrate 21. The solder joint defects are more likely to occur at the solder joint portion between the intermediate connection member 24 and the main substrate 10 than at the solder joint portion between the intermediate connection member 24 and the intermediate substrate 21. Accordingly, by performing a solder pre-coating process on mounting lands 242B of the intermediate connection member 24 that are to be mounted on the main substrate 10 before the intermediate substrate module 20 is mounted on the main substrate 10, the occurrence of solder joint defects can be reduced. In the solder pre-coating process, for example, before singulation of the intermediate connection member 24 into individual pieces, a predetermined amount of solder is printed onto the mounting lands 242B, followed by solder melting at the reflow oven and solidifying the solder, thereby forming a solder coating on the mounting lands 242B. Thereafter, after the components of the intermediate substrate module 20 are mounted, solder printing is again performed on the mounting lands of the main substrate 10, and the pre-coated intermediate substrate module 20 is mounted thereon. By employing such a mounting process, the mounting height of the intermediate connection member 24 relative to the main substrate 10 can be increased by a predetermined amount. The solder-induced height increase serves to increase the adjustment margin for the relative proximity or separation of the substrates caused by thermal warpage of the main substrate 10, thereby reducing the occurrence of solder joint defects.

Applying the pre-coating process to the mounting lands 242A of the intermediate connection member 24 that are to be mounted on the intermediate substrate 21 can further reduce the risk of solder joint defects during mounting of the intermediate substrate module 20. However, as described above, since the intermediate substrate 21 has a small substrate outer shape, as long as its remaining copper balance is properly designed to prevent bias between the front and back conductive layers of the intermediate substrate 21, thermal warpage during reflow can be relatively suppressed during the reflow mounting of the intermediate substrate 21. Moreover, applying the pre-coating process to both sides of the intermediate connection member 24 increases the manufacturing steps, man-hours, and cost. Therefore, the mounting height (solder joint height) Ha between the intermediate connection member 24 and the intermediate substrate 21 may be smaller than the mounting height Hb between the intermediate connection member 24 and the main substrate 10. Such a structure ensures a favorable balance between mounting quality and manufacturing efficiency, and thus solder pre-coating may be performed on only one side.

As described previously, the intermediate connection member 24 includes a base material made of an insulating material in which through-holes 241 are formed at predetermined intervals to allow electrical conduction between both sides. The through-holes 241 are filled with resin or the like and then capped by plating on both surfaces, whereupon the mounting lands 242A and 242B are formed directly above the plated through-hole lands. Through this manufacturing process, the intermediate connection member 24 can form a large number of through-holes 241 and mounting lands 242A and 242B at a narrow pitch. The mounting land pitch is sufficiently smaller than the mounting land pitch of the RAM 22 electrodes, which are general-purpose components, thereby enabling aggregation of electrode connectors and formation of a high-density component connection region.

FIG. 3B is a schematic diagram illustrating details of the mounting lands between the intermediate connection member 24 and the intermediate substrate 21. In manufacturing the intermediate substrate module 20, a cream solder (not illustrated) is previously printed or transferred between these mounting lands, followed by reflow mounting to join the opposing lands to each other. The structure of the mounting land can generally be classified into two types, namely a Solder Mask Defined (SMD) structure and a Non Solder Mask Defined (NSMD) structure. In the SMD structure, the contour shape of the mounting land is defined by a solder mask, that is, by a solder resist layer. In the NSMD structure, the contour shape of the mounting land is defined by an etching process of a conductor pad, and the boundary surface of the solder resist is set at a predetermined distance away from the conductor pad. In FIG. 3B, the mounting lands 242A of the intermediate connection member 24 are formed in an SMD-type land design, whereas the mounting lands (joined terminal portion) 212 of the intermediate substrate 21 are formed in an NSMD-type land design. In the mounting land 242A, the peripheral portion of the conductor pad is covered with a solder resist 242C, and the outer shape of the mounting land 242B is defined by the contour shape of the solder resist 242C. In the mounting land 212, the solder resist 213 is disposed at a predetermined distance away from the mounting land 212, and the outer shape of the conductor pad is determined by its own etching process. As discussed above, in consideration of the occurrence of mounting defects such as solder bridging or open joints at the solder joint portions, a solder pre-coating process may be performed on the mounting lands 242B on the main substrate 10 side, which are relatively disadvantageous to thermal warpage. At this time, although the mounting lands 242A on the intermediate substrate 21 side are relatively beneficial to thermal warpage, other countermeasures in addition to solder pre-coating may also be considered. Among such countermeasures, the application of an NSMD-type mounting land structure to the mounting lands 242A is proposed. In the NSMD structure, no solder resist layer is developed around the conductor pad. When the substrates come close to each other due to thermal warpage during reflow mounting, the molten solder may be pressed outward and swollen toward the peripheral portion of the conductor pad. In the case of an SMD structure, the solder resist layer defining the outer shape of the mounting land may further press the swollen molten solder, causing the solder to flow out beyond the land, thereby potentially forming floating conductors such as solder balls. Accordingly, the NSMD structure can form the space that allows the molten solder to remain around the conductor pad, which has been pressed by the solder resist that has been retracted from around the conductor pad. Therefore, the NSMD structure can effectively function as one countermeasure for preventing mounting defects such as solder bridging and solder ball generation during reflow mounting.

### Second Embodiment

This embodiment will discuss only the structures different from those in the first embodiment, and will omit a description of the common structures.

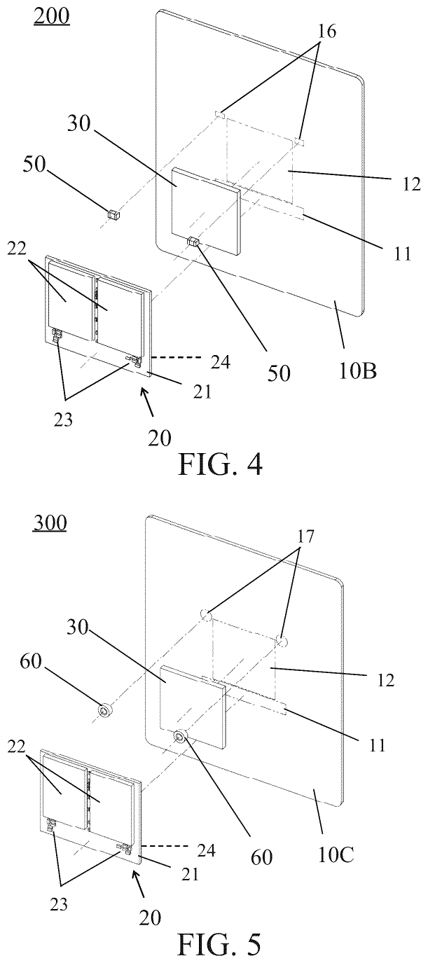

FIG. 4 is an exploded perspective view schematically illustrating a PCB module 200 according to this embodiment. Similarly to the PCB module 100, the PCB module 200 has a structure in which the intermediate substrate module 20 is three-dimensionally mounted above the video processing IC 30. Mounted on one surface of the intermediate substrate 21 are a RAM 22 and passive electronic components 23, and mounted on the other surface is an intermediate connection member 24. The main substrate 10B includes an image-processing-IC mounting land 12 on which the video processing IC 30 is mounted, intermediate-connection-member mounting lands 11 formed around the image processing IC mounting land 12, and two passive-component mounting lands 16. The passive-component mounting lands 16 include general-purpose passive electronic components 50. The passive electronic components 50 may be, for example, components such as ceramic capacitors, chip resistance elements, or inductor elements, having substantially the same component height as that of the intermediate connection member 24.

Using the general-purpose passive electronic components 50 as substrate support members instead of the spacers 40, this embodiment can reduce the operation for cutting the spacers 40 from a worksheet, the tray stacking operation, etc. during manufacture of the intermediate substrate module 20. Furthermore, the use of the general-purpose passive electronic components 50 facilitates application to automatic machines such as chip mounters, thereby improving manufacturing efficiency.

Similarly to the first embodiment, in order to improve the solder joint reliability of the intermediate connection member 24, the passive electronic components 50 are soldered to the main substrate 10B to support and hold the intermediate substrate module 20, while no fixed joining is performed between the passive electronic components 50 and the intermediate substrate 21; they are configured only to provide contact support. Alternatively, the passive electronic components 50 may be mounted on the intermediate substrate 21 and brought into contact support with the main substrate 10B.

### Third Embodiment

This embodiment will discuss only the structures different from those in the first embodiment, and will omit a description of the common structures.

FIG. 5 is an exploded perspective view schematically illustrating a PCB module 300 according to this embodiment. Similarly to the PCB module 100, the PCB module 300 has a structure in which the intermediate substrate module 20 is three-dimensionally mounted above the video processing IC 30. Mounted on one surface of the intermediate substrate 21 are a RAM 22 and passive electronic components 23, and mounted on the other surface is an intermediate connection member 24. The main substrate 10C includes an image-processing-IC mounting land 12 on which the video processing IC 30 is mounted, intermediate connection member mounting lands 11 formed around the image processing IC mounting land 12, and two metal-spacer mounting lands 17. The metal-spacer mounting lands 17 include general-purpose metal spacers 60. The metal spacers 60 may be, for example, onboard spacers, onboard tapped spacers, or onboard chip rings, having a component height substantially equal to that of the intermediate connection member 24. Using such general-purpose metal spacers 60 as substrate support members can improve manufacturing efficiency.

Similarly to the first embodiment, in order to improve the solder joint reliability of the intermediate connection member 24, the metal spacers 60 are soldered to the main substrate 10C to support and hold the intermediate substrate module 20, while no fixed joining is performed between the metal spacers 60 and the intermediate substrate 21; they are configured only to provide contact support. Alternatively, the metal spacers 60 may be mounted on the intermediate substrate 21 and brought into contact support with the main substrate 10C. Further, the metal spacers 60 may be replaced with other metal components, as long as they serve to contact-support the intermediate substrate module 20. For example, metal rings or metal washers may also be employed.

### Fourth Embodiment

This embodiment will discuss only the structures different from those in the first embodiment, and will omit a description of the common structures.

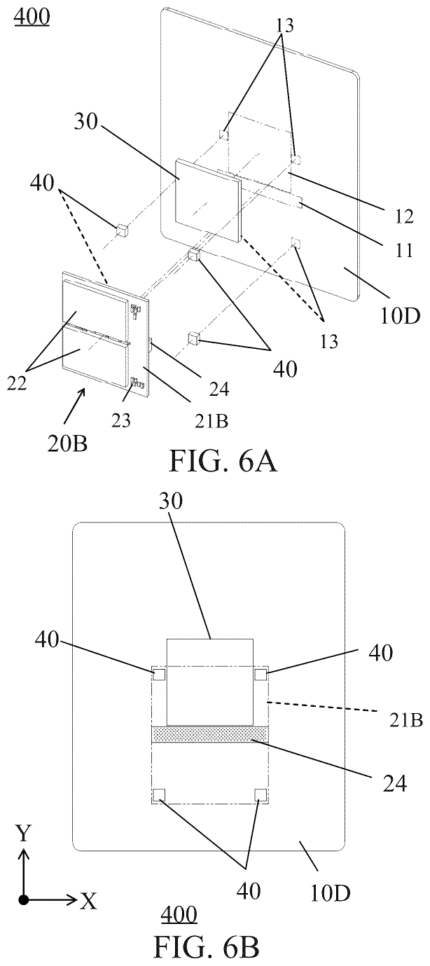

FIGS. 6A and 6B are schematic diagrams illustrating a PCB module 400 according to this embodiment. FIG. 6A is an exploded perspective view of the PCB module 400, and FIG. 6B is a front view of the PCB module 400. In FIG. 6B, the intermediate substrate 21B is illustrated as transparent for convenience of illustration.

Similarly to the PCB module 100, the PCB module 400 has a structure in which an intermediate substrate module 20B is three-dimensionally mounted above the video processing IC 30. Mounted on one surface of the intermediate substrate 21B are a RAM 22 and passive electronic components 23, and mounted on the other surface is an intermediate connection member 24. The intermediate connection member 24 is mounted at a substantially central region of the intermediate substrate 21B, corresponding to a middle position between the two RAMs 22. The main substrate 10D includes an image-processing-IC mounting land 12 on which the video processing IC 30 is mounted, intermediate-connection-member mounting lands 11 formed around the image-processing-IC mounting land 12, and two spacer mounting lands 13. Further, two additional spacer mounting lands 13 are formed at positions that are equidistant from the intermediate-connection-member mounting lands 11, across their mounting region. In order to further reduce the module outer shape of the intermediate substrate module 20B in the X direction, the RAMs 22 are arranged along the Y direction. By placing the intermediate connection member 24 at the central portion of the intermediate substrate 21B, the wiring lengths from the two RAMs 22 can be substantially equal. To stably mount the intermediate substrate module 20B onto the main substrate 10D, the spacer mounting lands 13 are formed so as to contact the four corner regions of the intermediate substrate module 20B, and spacers 40 are mounted thereon.

The structure according to this embodiment can reduce the sizes of the main substrate 10D and the intermediate substrate module 20B in the X direction. Alternatively, if the intermediate substrate module 20B can be stably mounted and held on the main substrate 10D solely by the intermediate connection member 24, all of the spacers 40 can be omitted based on the component mounting process or the assembly quality of the electronic apparatus. In a case where the spacers 40 are provided, in order to enhance the solder joint reliability of the intermediate connection member 24B, each spacer 40 is soldered to the main substrate 10D to hold the intermediate substrate module 20B, while no fixed joining is performed between the spacer 40 and the intermediate substrate 21B; the spacers are configured only to provide contact support. Alternatively, the spacers 40 may be mounted on the intermediate substrate 21B and brought into contact support with the main substrate 10D.

### Fifth Embodiment

This embodiment will discuss only the structures different from those in the first embodiment, and will omit a description of the common structures.

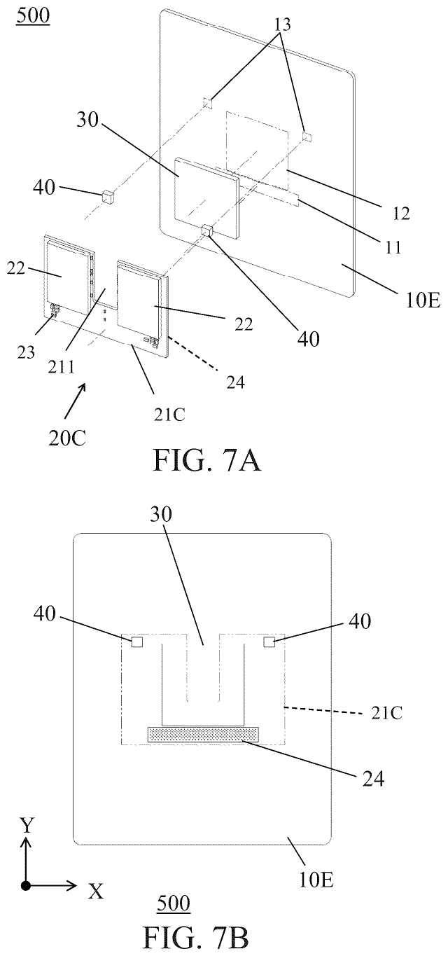

FIGS. 7A and 7B are schematic diagrams illustrating a PCB module 500 according to this embodiment. FIG. 7A is an exploded perspective view of the PCB module 500, and FIG. 7B is a front view of the PCB module 500. In FIG. 7B, the intermediate substrate 21C is illustrated as transparent for convenience of illustration.

Similarly to the PCB module 100, the PCB module 500 has a structure in which an intermediate substrate module 20C is three-dimensionally mounted above the video processing IC 30. Mounted on one surface of the intermediate substrate 21C are a RAM 22 and passive electronic components 23, and mounted on the other surface is an intermediate connection member 24. In this embodiment, the two RAMs 22 on the intermediate substrate 21C are spaced apart by a predetermined distance, and a cutout portion 211 is formed between the components. The main substrate 10E includes an image processing IC mounting land 12 on which the video processing IC 30 is mounted, intermediate-connection-member mounting lands 11 formed around the image-processing-IC mounting land 12, and two spacer mounting lands 13. When the intermediate substrate module 20C is mounted on the main substrate 10E, a part of the package outer shape of the video processing IC 30 is exposed externally through the cutout portion 211. Due to this structure, a so-called Thermal Interface Material (TIM) can be disposed on the exposed portion of the video processing IC 30. The TIM material is attached on one side to the package surface of the video processing IC 30, and on the other side is brought into contact with a metallic component or the like within the electronic apparatus, thereby transferring heat generated by the video processing IC 30 during operation to a variety of locations within the electronic apparatus. The TIM material may be properly selected depending on the application, and include, for example, a heat dissipation sheet formed by processing an elastic material into a sheet shape, or a gap filler composed of a paste-like material injected between components.

To enhance the solder joint reliability of the intermediate connection member 24, each spacer 40 is soldered to the main substrate 10E to hold the intermediate substrate module 20C, while no fixed joining is performed between the spacer 40 and the intermediate substrate 21C; the spacers are configured only to provide contact support. Alternatively, the spacers 40 may be mounted on the intermediate substrate 21C and brought into contact support with the main substrate 10E.

### Sixth Embodiment

This embodiment will discuss only the structures different from those in the first embodiment, and will omit a description of the common structures.

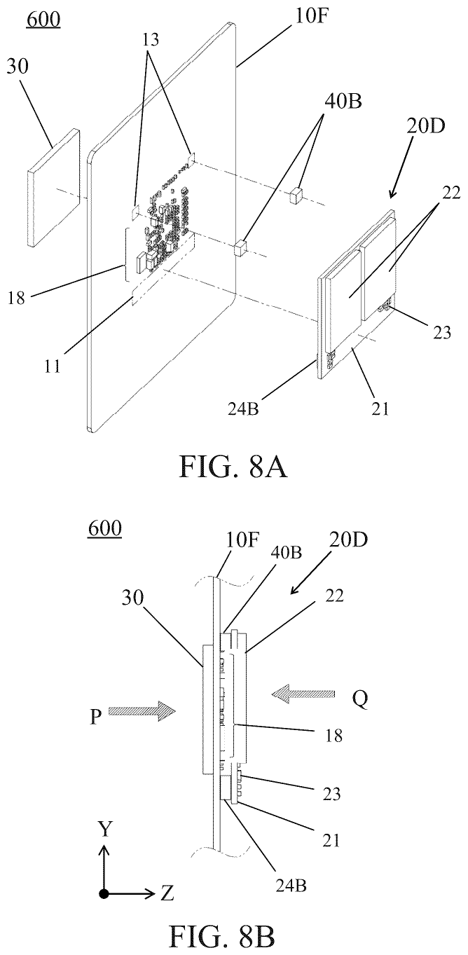

FIGS. 8A and 8B are schematic diagrams illustrating a PCB module 600 according to this embodiment. FIG. 8A is an exploded perspective view of the PCB module 600, and FIG. 8B is a front view of the PCB module 600.

Unlike the PCB module 100, the PCB module 600 has a structure in which an intermediate substrate module 20D is three-dimensionally mounted on the back surface of the main substrate 10F, which is opposite to the surface on which the video processing IC 30 is mounted. Mounted on the back surface of the main substrate 10F are electronic components 18 in a region corresponding to the area where the video processing IC 30 is mounted. The electronic components 18 include a bypass capacitor for each power supply line, disposed directly beneath the power supply electrode of the video processing IC 30. The power supply wiring is connected from the mounting land for the power supply electrodes of the video processing IC 30 to the back surface of the substrate via vias or through holes, and is connected to the electrodes of the bypass capacitors along a short path, thereby realizing stable operation during high-speed processing. The thickness of the intermediate connection member 24B is determined based on possible contact with the tallest one among the electronic components 18, and the thickness of the spacer 40B for supporting the intermediate substrate module 20D is set to be substantially equal to that of the intermediate connection member 24B.

Due to this structure, for example, a TIM material can be attached to the package surface of the video processing IC 30 or the package surface of the RAM 22. One side of the TIM material is attached to the package surface of the video processing IC 30 or RAM 22, and the other side is brought into contact with a metallic component or the like within the electronic apparatus, thereby transferring the heat generated by the video processing IC 30 or RAM 22 to a variety of parts within the electronic apparatus. In this embodiment, the TIM material may be attached to the package surface of the video processing IC 30 from a direction P, and to the package surface of the RAM 22 from the opposite direction Q. Thus, heat paths can be formed in two directions for transferring heat from the interior of the packages to metallic components or the like.

To enhance the solder joint reliability of the intermediate connection member 24B, the spacer 40B is soldered to the main substrate 10F to hold the intermediate substrate module 20D, while no fixed joining is performed between the spacer 40B and the intermediate substrate 21; the spacer is configured only to provide contact support. Alternatively, the spacer 40B may be mounted on the intermediate substrate 21 and brought into contact support with the main substrate 10F.

### Seventh Embodiment

This embodiment will discuss only the structures different from those in the first embodiment, and will omit a description of the common structures.

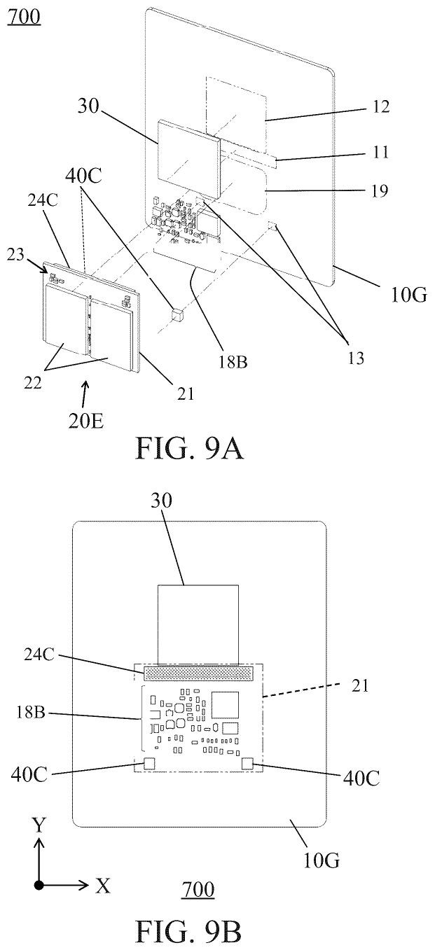

FIGS. 9A and 9B are schematic diagrams illustrating a PCB module 700 according to this embodiment. FIG. 9A is an exploded perspective view of the PCB module 700, and FIG. 9B is a front view of the PCB module 700.

In the PCB module 700, unlike the PCB module 100, spacer mounting lands 13 are formed at positions equidistant from the mounting region of the intermediate-connection-member mounting lands 11, so as to extend across the mounting region of the intermediate-connection-member mounting lands 11. A main substrate 10G includes, in a region surrounded by the intermediate-connection-member mounting lands 11 and the two spacer mounting lands 13, an electronic-component mounting land 19 on which other electronic components can be mounted. After an electronic component 18B is mounted on the electronic-component mounting land 19, an intermediate substrate module 20E is mounted and reflow-soldered.

The substrate thickness of the intermediate connection member 24C is set based on possible contact with the tallest one among the electronic components 18B. The board thickness of the spacer 40B that supports the intermediate substrate module 20E is set to be equal to that of the intermediate connection member 24B.

Due to this structure, for example, a heat-dissipating structure can be formed by attaching a TIM to the package surfaces of both the video processing IC 30 and the RAM 22 from the same direction. One side of the TIM material is adhered to the package surface of the video processing IC 30 or the RAM 22, and the other side is brought into contact with a metal member or the like within the electronic device, thereby transferring heat generated by the video processing IC 30 or the RAM 22 during operation to a variety of parts inside the electronic apparatus.

To enhance the solder joint reliability of the intermediate connection member 24C, the spacer 40C is soldered to the main substrate 10G so as to support and retain the intermediate substrate module 20E. No fixed connection is made between the spacer 40C and the intermediate substrate 21; rather, they are configured to provide contact support only. Alternatively, the spacer 40C may be mounted on the intermediate substrate 21 and configured to provide contact support with the main substrate 10G.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

Each embodiment can provide a PCB module that can suppress constraints on the arrangement of electronic components and on the surface-layer wiring of an external board.

This application claims the benefit of Japanese Patent Application No. 2024-230752, filed on Dec. 26, 2024, which is hereby incorporated by reference herein in its entirety.

What is claimed is:

1. A printed circuit board module comprising:
a first printed circuit board having a first surface on which a processor component is mounted;
a second printed circuit board having a second surface on which a memory component is mounted, the second surface being parallel to the first surface, and the second printed circuit board being disposed apart from the first printed circuit board;
a connection member mounted on and disposed between the first printed circuit board and the second printed circuit board so that the connection member opposes a first side of a package outer shape of the processor component in a projection view in a first direction perpendicular to the first surface, the connection member electrically connecting the first printed circuit board and the second printed circuit board; and
a plurality of support members disposed between the first printed circuit board and the second printed circuit board and supporting the first and second printed circuit boards,
wherein the plurality of support members are disposed apart from each other and each of the plurality of support members is disposed apart from the connection member.

2. The printed circuit board module according to claim 1, wherein the first surface opposes the second printed circuit board.

3. The printed circuit board module according to claim 2, wherein a back surface of the second surface opposes the first surface.

4. The printed circuit board module according to claim 2, wherein at least a part of a wiring line that connects the processor component and another electronic component mounted on the first printed circuit board is formed on a surface layer of the first printed circuit board outside an area where the connection member is mounted.

5. The printed circuit board module according to claim 1, wherein a back surface of the first surface opposes the second printed circuit board.

6. The printed circuit board module according to claim 1, wherein at least a part of the memory component overlaps the processor component in the projection view in the first direction.

7. The printed circuit board module according to claim 1, wherein the second printed circuit board does not overlap the processor component in the projection view in the first direction.

8. The printed circuit board module according to claim 1, wherein the memory component includes a first memory component and a second memory component arranged in a direction parallel to a direction in which the processor component and the connection member oppose each other, and
wherein the connection member is disposed such that distances from the connection member to each of the first memory component and the second memory component are equal in the projection view in the first direction.

9. The printed circuit board module according to claim 1, wherein the second printed circuit board has at least one of a cutout portion and a perforation hole to expose the processor component in the projection view in the first direction.

10. The printed circuit board module according to claim 1, further comprising an electronic component having a component height equal to or less than a component height of the processor component and mounted on the first surface near a side different from the first side of the package outer shape.

11. The printed circuit board module according to claim 1, wherein the processor component is at least one of an image processing processor and a video processing processor, and
wherein the memory component is configured to temporarily store a task to be executed by the processor component.

12. The printed circuit board module according to claim 1, wherein the processor component includes a plurality of electrode portions electrically connected to the first printed circuit board, and
wherein a first electrode portion among the plurality of electrode portions that is electrically connected to the memory component is disposed on a side of and along the first side.

13. The printed circuit board module according to claim 1, wherein the support members are disposed close to both end portions of a second side opposite to the first side in the projection view in the first direction.

14. The printed circuit board module according to claim 1, wherein the support members are joined with one of the first printed circuit board and the second printed circuit board and contacts the other of the first printed circuit board and the second printed circuit board.

15. The printed circuit board module according to claim 1, wherein the connection member and the support members are separated from the same worksheet.

16. The printed circuit board module according to claim 1, wherein each of the connection member and the support members has a rectangular shape in the projection view in the first direction.

17. The printed circuit board module according to claim 1, wherein the connection member is joined with the first printed circuit board and the second printed circuit board with solder, and
wherein a solder joint height between the connection member and the first printed circuit board is greater than a solder joint height between the connection member and the second printed circuit board.

18. The printed circuit board module according to claim 1, wherein a joined terminal portion of the second printed circuit board used for solder joint with the connection member is formed in a land design of a NSMD type.

19. The printed circuit board module according to claim 1, wherein the connection member has a through-hole that electrically connects the first printed circuit board and the second printed circuit board, and
wherein an interior of the through-hole is filled with a sealing material, and a mounting land is formed by plating a cap layer on a surface of a pad portion.

20. The printed circuit board module according to claim 1, wherein the plurality of support members include a passive electronic component.

21. The printed circuit board module according to claim 1, wherein the plurality of support members include any one of a metal spacer, a metal ring, or a metal washer.

22. The printed circuit board module according to claim 1, wherein in the projection view in the first direction, a total projected area of the connection member and the plurality of support members is 50% or less of a projected area of the processor component.
